(19) United States
(12) Patent Application Publication
(10) Pub. No.: US 2023/0018843 A1
(43) Pub. Date: Jan. 19, 2023

(54) MOTOR, AND DISK DRIVE APPARATUS

(71) Applicant: NIDEC CORPORATION, Kyoto (JP)

(72) Inventors: Masahiro IMAHORI, Kyoto (JP); Kazuhiro SATO, Kyoto (JP); Tomoki UCHIBORI, Kyoto (JP)

(73) Assignee: NIDEC CORPORATION, Kyoto (JP)

(21) Appl. No.: 17/865,366

(22) Filed: Jul. 14, 2022

(30) Foreign Application Priority Data
Jul. 16, 2021 (JP) 2021-117672

(51) Int. Cl. H02K 5/167; H01L 35/30; H02K 7/00; H02K 7/08; H02K 21/22; G11B 17/02

(52) U.S. Cl. CPC H02K 5/1677; H01L 35/30; H02K 7/003; H02K 7/088; H02K 21/22; G11B 17/02

(57) ABSTRACT

A motor includes a shaft, a base, a stator, a rotor, a bearing, and at least one or more temperature adjusters. The shaft extends along a central axis extending in an axial direction. The base extends in a radial direction from an end of the shaft in an axially one direction. The stator has an annular shape surrounding the shaft, and is disposed further in an axially other direction than the base. The rotor is rotatable about the central axis. The bearing rotatably supports the rotor. The temperature adjuster adjusts an ambient temperature of the bearing. The shaft has a shaft hole recessed in the axial direction from an axial end of the shaft. The temperature adjuster is disposed in the shaft hole and overlaps at least a portion of the bearing as viewed in the radial direction.

### CROSS REFERENCE TO RELATED APPLICATIONS

The present invention claims priority under 35 U.S.C. § 119 to Japanese Application No. 2021-117672 filed on Jul. 16, 2021 the entire content of which is incorporated herein by reference.

### FIELD OF THE INVENTION

The present disclosure relates to a motor and a disk drive apparatus.

### BACKGROUND

Conventionally, a disk drive apparatus such as a hard disk drive is equipped with a motor that rotates a disk. For example, a spindle motor for a hard disk drive includes a first and second conical bearing member, a rotor member, a dynamic pressure groove, and a lubricant. The first and second conical bearing members are fixed to a shaft member and have a conical outer surface. The rotor member has a first and second conical inner surface whose inner diameter increases outward. The dynamic pressure groove is provided on either the conical inner surface or the conical outer surface. The lubricant is filled in a small gap between the conical inner surface and the conical outer surface.

However, when a bearing temperature of the motor rises, there is a risk that rotation of the rotor may not be stable due to a change in viscosity of the lubricant filled in a bearing. Hence, in the conventional motor, it has been attempted to stabilize the rotation of the rotor by defining a relational expression of coefficient of linear expansion of each of the shaft member, the conical bearing member and the rotor member, and a relational expression between an axial distance between a first point and a second point of the same inner diameter on the first and second conical inner surfaces, an inner diameter dimension at the first point, and an inclination angle defined by the conical inner surface with a surface perpendicular to an axis. However, there is a risk that the rotation of the rotor cannot be sufficiently stabilized only by controlling the coefficient of linear expansion and the shape of members.

### SUMMARY

A motor according to an exemplary embodiment of the disclosure includes a shaft, a base, a stator, a rotor, a bearing, and at least one or more temperature adjusters. The shaft extends along a central axis extending in an axial direction. The base extends in a radial direction from an end of the shaft in an axially one direction. The stator has an annular shape surrounding the shaft, and is disposed further in an axially other direction than the base. The rotor is rotatable about the central axis. The bearing rotatably supports the rotor. The temperature adjuster adjusts an ambient temperature of the bearing. The shaft has a shaft hole recessed in the axial direction from an axial end of the shaft. The temperature adjuster is disposed in the shaft hole and overlaps at least a portion of the bearing as viewed in the radial direction.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a cross-sectional view illustrating a configuration example of a disk drive apparatus.

FIG. 2 is a cross-sectional view illustrating a configuration example of a motor.

FIG. 3 is a cross-sectional view illustrating a configuration example of a motor according to a modification.

### DETAILED DESCRIPTION

An exemplary embodiment will be described below with reference to the drawings.

In the present specification, in a disk drive apparatus 100 and a motor 1, a direction parallel to a central axis CX is referred to as an “axial direction.” In the axial direction, a direction toward a base 40 from a rotor 20 to be described later is referred to as an “axially one direction D1,” and a direction toward the rotor 20 from the base 40 is referred to as an “axially other direction D2.”

A direction orthogonal to the central axis CX is referred to as a “radial direction,” and a direction of rotation about the central axis CX is referred to as a “circumferential direction.” In the radial direction, a direction approaching the central axis CX is referred to “radially inward,” and a direction away from the central axis CX is referred to “radially outward.” In each component, an end located radially inside is referred to as a “radially inner end,” and an end located radially outside is referred to as a “radially outer end.” In a side surface of each component, a side surface facing radially inward is referred to as a “radially inner surface”, and a side surface facing radially outward is referred to as a “radially outer surface.”

In the present specification, an “annular shape” includes, in addition to a shape that is continuously connected without a break over the entire circumferential direction centered on the central axis CX, a shape with one or more breaks in a portion of the entire area centered on the central axis CX. Also included is a shape that draws a closed curve about the central axis CX on a curved surface intersecting the central axis CX.

In a positional relationship between any one and any other of orientation, line and surface, “parallel” includes not only a state in which the aforesaid two do not intersect at all no matter how long they extend, but also a state in which they are substantially parallel. “Perpendicular” and “orthogonal” include not only a state in which the aforesaid two intersect each other at 90 degrees, but also a state in which they are substantially perpendicular to each other and a state in which they are substantially orthogonal to each other, respectively. That is, “parallel,” “perpendicular” and “orthogonal” each include a state in which the positional relationship between the aforesaid two has an angular deviation without departing from the gist of the disclosure.

The above names are only used for description and are not intended to limit the actual positional relationships, directions, and names.

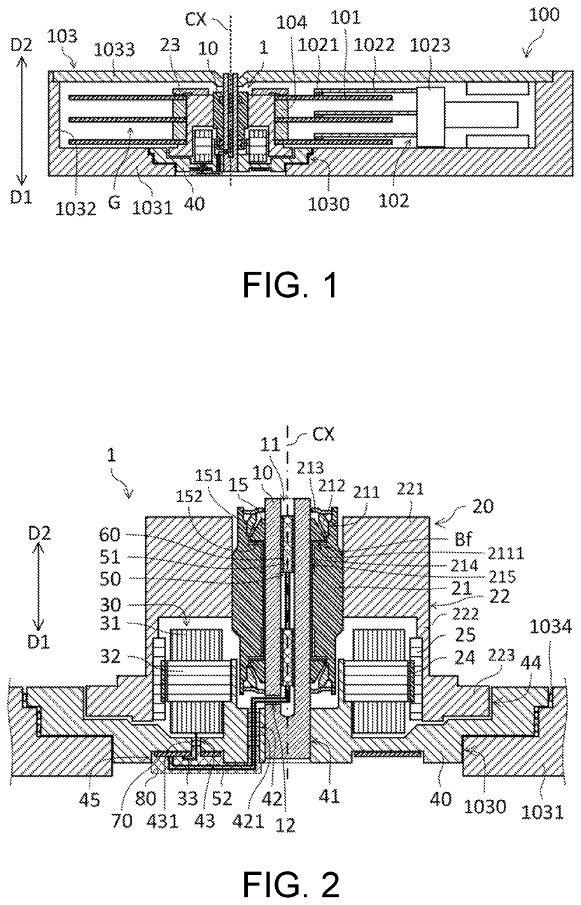

FIG. 1 is a cross-sectional view illustrating a configuration example of the disk drive apparatus 100. FIG. 1 illustrates a cross-sectional structure of the disk drive apparatus 100 cut along a virtual plane containing the central axis CX.

The disk drive apparatus 100 of the present embodiment is a hard disk drive. The disk drive apparatus 100 includes the motor 1, a disk 101 supported by the motor 1, and an access part 102. The access part 102 at least either reads information from or writes information to the disk 101. As will be described later, since the motor 1 is able to adjust an ambient temperature of a fluid dynamic pressure bearing Bf, the disk drive apparatus 100 is able to rotate the disk 101 accurately and stably without depending on the ambient temperature of the fluid dynamic pressure bearing Bf. Accordingly, a speed at which the access part 102 reads information from or writes information to the disk 101 is able to be stably improved.

The disk 101 is a medium on which information is recorded. The number of the disk 101 is three in the present embodiment, as illustrated in FIG. 1. However, the disclosure is not limited to this illustration. The disk 101 may be singular or plural (other than three) in number. The disk 101 is disposed on a radially outer surface of the rotor 20 (to be described later) of the motor 1, and is axially laminated via a spacer 104. The disk 101 is rotatably supported by the motor 1 about the central axis CX. When the disk drive apparatus 100 operates, the disk 101 is rotated by driving of the motor 1.

The access part 102 includes a plurality of heads 1021, a plurality of arms 1022, and a head movement mechanism 1023. The head 1021 approaches a surface of the disk 101, and at least either magnetically reads the information recorded on the disk 101 or magnetically writes information to the disk 101. The head 1021 is disposed at one end of the arm 1022 close to the motor 1 and is supported by the arm 1022. The other end of the arm 1022 is supported by the head movement mechanism 1023.

The disk drive apparatus 100 further includes a housing 103. The housing 103 houses the motor 1, the disk 101, and the access part 102. The housing 103 has an opening 1030, a bottom plate 1031, a side plate 1032, and a top plate 1033. The bottom plate 1031 and the top plate 1033 extend in a direction perpendicular to the central axis CX. The opening 1030 is disposed in the bottom plate 1031 and penetrates the bottom plate 1031 in the axial direction. The motor 1 is disposed on the bottom plate 1031. In detail, the base 40 (to be described later) of the motor 1 is fitted into the opening 1030 and is connected to the bottom plate 1031 via a seal member 1034 (see FIG. 2 to be described later) such as a metal gasket. Here, the bottom plate 1031 is separate from the base 40 in the present embodiment. However, the disclosure is not limited to the illustration of the present embodiment. The bottom plate 1031 may be integrated with the base 40. The side plate 1032 has a tubular or substantially tubular shape extending in the axially other direction D2 from an outer edge of the bottom plate 1031, and surrounds the motor 1, the disk 101 and the access part 102. The side plate 1032 is integrated with the bottom plate 1031 in the present embodiment. However, the side plate 1032 may be separate from the bottom plate 1031. The top plate 1033 is disposed at an end of the side plate 1032 close to the axially other direction D2, and covers an opening at the end of the side plate 1032 close to the axially other direction D2. The bottom plate 1031 and the base 40 are combined with each other, and the side plate 1032 and the top plate 1033 are combined with each other, so that airtightness in the housing 103 is not impaired.

The bottom plate 1031, the side plate 1032 and the top plate 1033 define a closed space inside the housing 103 together with the base 40 of the motor 1. The housing 103 (that is, the above-mentioned closed space) is filled with a gas G having a lower density than air. As the gas G, helium gas is used in the present embodiment. However, the disclosure is not limited to this illustration, and a mixed gas of hydrogen gas, He and H₂ may be used for the gas G. In this way, fluid resistance acting on the rotor 20 and the disk 101 during rotational driving of the motor 1 and the disk 101 is able to be reduced.

A configuration of the motor 1 is described with reference to FIG. 1 and FIG. 2. FIG. 2 is a cross-sectional view illustrating a configuration example of the motor 1. FIG. 2 illustrates a cross-sectional structure of the motor 1 cut along a virtual plane containing the central axis CX. In FIG. 2, a clamp member 23 to be described later is omitted from illustration.

The motor 1 is a DC spindle motor in the present embodiment. The motor 1 includes a shaft 10, a pair of thrust tubes 15, the rotor 20, a stator 30, the base 40, a temperature adjuster 50, a heat conductor 60, a substrate 70 and a cover 80.

The shaft 10 has a columnar or substantially columnar shape and extends along the central axis CX. The central axis CX extends along the axial direction. As described above, the motor 1 includes the shaft 10. The shaft 10 rotatably supports the rotor 20 about the central axis CX. The shaft 10 is defined of metal such as stainless steel. An end of the shaft 10 close to the axially one direction D1 is connected to the base 40. An end of the shaft 10 close to the axially other direction D2 is fixed to the top plate 1033 of the housing 103.

The shaft 10 has a shaft hole 11. The shaft hole 11 is recessed in the axial direction from an axial end of the shaft 10. For example, in the present embodiment, the shaft hole 11 is recessed in the axially one direction D1 from the end of the shaft 10 close to the axially other direction D2, and extends further in the axially one direction D1 than the fluid dynamic pressure bearing Bf (to be described later) close to the axially one direction D1.

The shaft 10 further has a communication hole 12. The communication hole 12 penetrates the shaft 10 in the radial direction. The communication hole 12 is disposed further in the axially one direction D1 than the fluid dynamic pressure bearing Bf close to the axially one direction D1. In this way, a connection line 52 (to be described later) of the temperature adjuster 50 is able to be pulled out of the shaft 10 through, for example, the communication hole 12.

The pair of thrust tubes 15 has a tubular or substantially tubular shape extending in the axial direction and is disposed on a radially outer surface of the shaft 10 at both axial ends of the shaft 10. Each thrust tube 15 may be integrated with or separate from the shaft 10. Each thrust tube 15 has an outer peripheral surface 151 and a facing surface 152. The outer peripheral surface 151 extends in a direction diagonally intersecting the central axis CX, and tilts radially inward as it goes from an axial center toward an axial end of the shaft 10. The facing surface 152 has an annular or substantially annular shape extending in a direction intersecting the central axis CX, faces a sleeve 21 (to be described later) of the rotor 20 in the axial direction, and defines a gap with the sleeve 21.

The rotor 20 is rotatable about the central axis CX. As described above, the motor 1 includes the rotor 20. The rotor 20 includes the sleeve 21, a rotor hub 22, the clamp member 23 (see FIG. 1), a magnet 24, and a yoke 25.

The sleeve 21 has a tubular or substantially tubular shape surrounding the central axis CX. The shaft 10 is inserted through the sleeve 21. The sleeve 21 is rotatably supported by the shaft 10 about the central axis CX. The sleeve 21 faces and defines a gap with the shaft 10 and the thrust tube 15. The gap is filled with a fluid (not illustrated) such as lubricant or gas.

The sleeve 21 includes a pair of recesses 211, a pair of collars 212, a pair of end caps 213, and a dynamic pressure groove part 214.

Each recess 211 is disposed at both axial ends of the sleeve 21 and is recessed from an axial end toward an axial center of the sleeve 21. The thrust tube 15 is housed inside the recess 211. A bottom surface 2111 of the recess 211 is a surface toward the axial end from the axial center of the sleeve 21, and faces the facing surface 152 of the thrust tube 15 in the axial direction.

Each collar 212 has an annular or substantially annular shape, and extends toward the central axis CX from an inner peripheral surface of the recess 211 that faces radially inward. Each collar 212 (particularly a radially inner surface thereof) extends toward the axial end from the axial center of the sleeve 21 as it goes radially inward. The radially inner surface of the collar 212 faces the outer peripheral surface 151 of the thrust tube 15.

Each end cap 213 is fitted into the recess 211 at both axial ends of the sleeve 21 and covers a gap between the shaft 10 and the axial end of the sleeve 21 in the radial direction. The end cap 213 has an annular or substantially annular shape surrounding the shaft 10 with a gap in the radial direction, and is disposed axially outside the collar 212 (in the direction toward the axial end from the axial center of the sleeve 21).

The dynamic pressure groove part 214 is disposed on an inner surface of the sleeve 21 and includes a dynamic pressure groove (not illustrate). That is, the dynamic pressure groove part 214 is a portion having a surface on which the dynamic pressure groove is provided. The dynamic pressure groove is a groove for generating dynamic pressure in the fluid interposed between the sleeve 21 and each of the shaft 10 and the thrust tube 15.

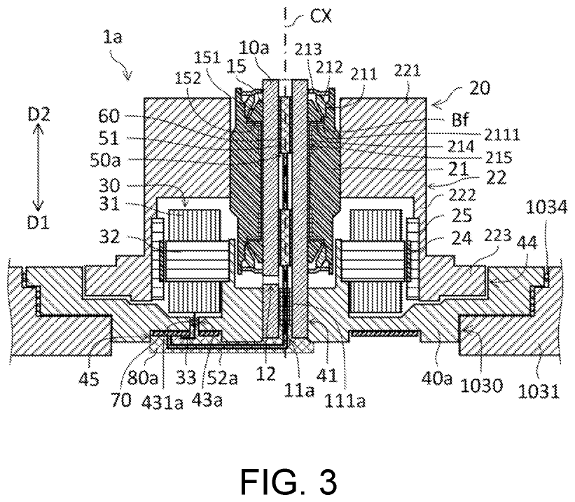

The dynamic pressure groove part 214 is disposed close to the sleeve 21 in the present embodiment. In detail, the dynamic pressure groove part 214 is disposed on each of the facing surface 215 of the sleeve 21 and the bottom surface 2111 of the recess 211. The facing surface 215 is a portion of the inner surface of the sleeve 21 that faces the radially outer surface of the shaft 10 via the fluid, and is a region of both axial ends in FIG. 3. However, the disclosure is not limited to the illustration of the present embodiment. The dynamic pressure groove part 214 is able to be disposed on at least one of the facing surface 215 and the bottom surface 2111. The dynamic pressure groove part 214 is able to be disposed on at least one side of the shaft 10 and the sleeve 21. For example, the dynamic pressure groove part 214 may be disposed on at least one of at least a portion of the radially outer surface of the shaft 10 and the facing surface 152 of the thrust tube 15.

In a portion where the sleeve 21 faces the shaft 10 and the thrust tube 15 via the fluid, a portion including the dynamic pressure groove part 214 functions as the fluid dynamic pressure bearing Bf. The fluid dynamic pressure bearing Bf is an example of a “bearing” of the disclosure. The motor 1 includes the fluid dynamic pressure bearing Bf. The fluid dynamic pressure bearing Bf rotatably supports the rotor 20. In detail, when the rotor 20 rotates with respect to the shaft 10, dynamic pressure is generated in the fluid by the dynamic pressure groove of the dynamic pressure groove part 214 in the above-mentioned portion. Due to this dynamic pressure, the sleeve 21 is separated from the shaft 10 and the thrust tube 15. Accordingly, the rotor 20 is rotatably supported while the fluid dynamic pressure bearing Bf and the rotor 20 are in no contact with each other.

The rotor hub 22 is fixed to a radially outer end of the sleeve 21, and is rotatable about the central axis CX together with the sleeve 21. The rotor hub 22 may be integrated with or separate from the sleeve 21. As a material of the sleeve 21 and the rotor hub 22, for example, a metal material such as aluminum or an alloy thereof or stainless steel is used.

The rotor hub 22 includes an annual part 221, a tube 222, and a flange 223. The annular part 221 extends radially outward from the radially outer end of the sleeve 21. The tube 222 has a tubular or substantially tubular shape extending in the axially one direction D1 from a radially outer end of the annular part 221 and is disposed radially outward of the stator 30. The flange 223 extends radially outward from an end of the tube 222 close to the axially one direction D1.

As illustrated in FIG. 1, the clamp member 23 supports the disk 101 together with the flange 223 of the rotor hub 22. In detail, a radially inner end of the clamp member 23 is supported by the annular part 221 of the rotor hub 22. The clamp member 23 sandwiches the disk 101 laminated via the spacer 104 between the clamp member 23 and the flange 223 in the axial direction.

The magnet 24 is fixed to an inner peripheral surface of the tube 222 of the rotor hub 22 via the yoke 25. The magnet 24 and the yoke 25 have an annular or substantially annular shape surrounding the central axis CX. The magnet 24 has a magnetic pole face where the north pole and the south pole are alternately arranged along the circumferential direction. The magnet 24 may be directly fixed to the inner peripheral surface of the rotor hub 22.

The stator 30 has an annular or substantially annular shape surrounding the shaft 10, and is disposed further in the axially other direction D2 than the base 40. As described above, the motor 1 includes the stator 30. The stator 30 faces the magnet 24 of the rotor 20 in the radial direction, and rotates the rotor 20 according to supply of electric power.

The stator 30 has a stator core 31. The stator core 31 is a laminated structure in which a plurality of magnetic materials having an annular or substantially annular shape centered on the central axis CX are laminated, and is fixed to the base 40. The stator core 31 has a plurality of teeth (not illustrated) protruding radially outward.

The stator 30 further includes a coil part 32 in which a conducting wire 33 is wound into a coil. Each coil part 32 is defined by the conducting wire 33 wound around a tooth via an insulator (not illustrated) having electrical insulation properties.

The base 40 extends in the radial direction from the end of the shaft 10 close to the axially one direction D 1. As described above, the motor 1 includes the base 40. The base 40 is, for example, molded by casting, and is die-cast aluminum in the present embodiment.

An opening 41 is disposed in the base 40. The opening 41 penetrates the base 40 in the axial direction. The end of the shaft 10 close to the axially one direction D1 is inserted through the opening 41 and fixed to the base 40.

The base 40 has a through hole 42. The through hole 42 penetrates the base 40 in the axial direction. For example, the connection line 52 of the temperature adjuster 50 pulled out of the shaft 10 is able to be pulled out of the motor 1 through the through hole 42.

Preferably, the through hole 42 is disposed near the shaft 10 in the radial direction. For example, in the present embodiment, the through hole 42 is disposed radially inward of the stator 30. In this way, the through hole 42 is able to be disposed near the communication hole 12 in the radial direction. Accordingly, a path length of the connection line 52 from the temperature adjuster 50 to the through hole 42 is able to be reduced. However, this illustration does not exclude a configuration in which the through hole 42 is not disposed radially inward of the stator 30.

In the present embodiment, the motor 1 further includes a sealing member 421 that seals the through hole 42. The sealing member 421 is disposed further in the axially one direction D1 than the temperature adjuster 50. In the present embodiment, an epoxy-based thermosetting resin is used for the sealing member 421. The sealing member 421 is an example of a “second sealing member” of the disclosure. In this way, airtightness inside the motor 1 is able to be enhanced by sealing the through hole 42. The motor 1 is housed in the closed space of the housing 103 filled with the gas G having a low density. Hence, by enhancing the airtightness inside the motor 1, it is able to be prevented that the gas G leaks from inside the motor 1 to the outside via the through hole 42. Accordingly, airtightness of the disk drive apparatus 100 (in other words, the closed space of the housing 103) is also able to be enhanced.

The base 40 further has a base hole 43. The base hole 43 penetrates the base 40 in the axial direction. For example, the conducting wire 33 of the coil part 32 is able to be pulled out of the motor 1 through the base hole 43. The base hole 43 is preferably disposed near the coil part 32. In the present embodiment, the base hole 43 is disposed directly under the coil part 32. That is, the base hole 43 overlaps the coil part 32 as viewed in the axial direction. In this way, a path length of the conducting wire 33 from the coil part 32 to the base hole 43 is able to be reduced.

In the present embodiment, the motor 1 further includes a sealing member 431 that seals the base hole 43. In the present embodiment, an epoxy-based thermosetting resin is used for the sealing member 431. A material of the sealing member 431 may be the same as or different from that of the sealing member 421. The sealing member 431 is an example of a “first sealing member” of the disclosure. In this way, the airtightness inside the motor 1 is able to be enhanced by sealing the base hole 43. It is able to be prevented that the gas G leaks from inside the motor 1 to the outside via the base hole 43. Accordingly, the airtightness of the disk drive apparatus 100 (in other words, the closed space of the housing 103) is also able to be enhanced.

The base 40 further includes a recess 44. The recess 44 is disposed in the axially other direction D2 with respect to the base 40, and is recessed in the axially one direction D1. The recess 44 is a groove having an annular or substantially annular shape centered on the central axis CX. The flange 223 of the rotor 20 is housed in the recess 44. A bottom surface of the recess 44 toward the axially other direction D2 faces the flange 223 in the axial direction. An inner surface of the recess 44 faces radially inward faces the flange 223 in the radial direction. In this way, a path length from one to the other of the inside and outside of the rotor 20 through between the recess 44 and the flange 223 is able to be increased. Accordingly, the airtightness inside the motor 1 is able to be enhanced.

The base 40 further includes a recess 45. The recess 45 is disposed in the axially one direction D1 with respect to the base 40, and is recessed in the axially other direction D2. The base hole 43 communicates with the recess 45.

The temperature adjuster 50 adjusts the ambient temperature of the fluid dynamic pressure bearing Bf. The motor 1 includes at least one temperature adjuster 50. For example, the temperature adjuster 50 adjusts the temperature of the fluid filled between the sleeve 21 and each of the shaft 10 and the thrust tube 15. The temperature adjuster 50 is disposed in the shaft hole 11. The temperature adjuster 50 overlaps at least a portion of the fluid dynamic pressure bearing Bf as viewed in the radial direction. That is, the temperature adjuster 50 is disposed in the same axial position as at least a portion of the fluid dynamic pressure bearing Bf. The number of the temperature adjuster 50 is the same as the number (that is, two) of the fluid dynamic pressure bearing Bf in the present embodiment. However, the disclosure is not limited to this illustration. The number of the temperature adjuster 50 may be different from the number of the fluid dynamic pressure bearing Bf. For example, the temperature adjuster 50 may be singular or plural (three or more) in number. A portion of the temperature adjuster 50 may be disposed in a different axial position from the fluid dynamic pressure bearing Bf.

In this way, the ambient temperature of the fluid dynamic pressure bearing Bf is able to be adjusted by the temperature adjuster 50 via the shaft 10. For example, when the rotor 20 rotates at high speed, an increase in the ambient temperature of the fluid dynamic pressure bearing Bf is able to be suppressed or prevented by the temperature adjuster 50. Accordingly, by suppressing or preventing a decrease in viscosity of the fluid due to a temperature rise, in which the fluid lubricates the fluid dynamic pressure bearing Bf, rotational shake or the like of the rotor 20 is able to be suppressed or prevented. Accordingly, the motor 1 is able to rotate the rotor 20 accurately and stably without depending on the ambient temperature of the fluid dynamic pressure bearing Bf.

In the present embodiment, the temperature adjuster 50 includes a Peltier element 51. By using the Peltier element 51, the ambient temperature of the fluid dynamic pressure bearing Bf is able to be adjusted by electrically driving the Peltier element 51.

In the present embodiment, the temperature adjuster 50 further includes the connection line 52. The connection line 52 is a lead that electrically connects the temperature adjuster 50 to the outside of the motor 1. In the present embodiment, the connection line 52 is pulled out of the shaft 10 through the communication hole 12 and pulled out of the base 40 through the through hole 42.

The temperature adjuster 50 is not limited to the above illustration. A member that adjusts the ambient temperature of the fluid dynamic pressure bearing Bf may be one other than the Peltier element 51. For example, the temperature adjuster 50 may include a heat pipe.

The heat conductor 60 is disposed between an inner peripheral surface of the shaft hole 11 and the temperature adjuster 50. As described above, the motor 1 further includes the heat conductor 60. The heat conductor 60 is a graphite sheet in the present embodiment. However, the disclosure is not limited to this illustration. A thermal tape, thermal grease or the like may be used for the heat conductor 60. The heat conductor 60 may further be disposed between the temperature adjusters 50 in the axial direction. In this way, heat transfer efficiency between the shaft 10 and the temperature adjuster 50 is able to be improved. Accordingly, the temperature adjuster 50 is able to relatively accurately adjust the ambient temperature of the fluid dynamic pressure bearing Bf.

The disclosure is not limited to the illustration of the present embodiment, and the heat conductor 60 may be omitted. That is, at least one temperature adjuster 50 may be in direct contact with the inner peripheral surface of the shaft hole 11.

The substrate 70 is equipped with a drive circuit (not illustrated) of the motor 1, a control part (not illustrated) of the temperature adjuster 50 (such as the Peltier element 51) or the like. The motor 1 includes the above-mentioned drive circuit and control part. As described above, the motor 1 includes the substrate 70. The substrate 70 is disposed further in the axially one direction D1 than the base 40, and is housed in the recess 45 of the base 40 in the present embodiment. The conducting wire 33 of the stator 30 and the connection line 52 of the temperature adjuster 50 are connected to the substrate 70. For example, the conducting wire 33 is connected to the substrate 70 through the base hole 43. The connection line 52 is connected to the substrate 70 through at least the through hole 42. As described above, the temperature adjuster 50 includes the connection line 52. By connecting the conducting wire 33 of the coil part 32 and the connection line 52 of the temperature adjuster 50 to the substrate 70, the adjustment of the ambient temperature of the fluid dynamic pressure bearing Bf by the temperature adjuster 50 according to rotational driving of the motor 1 is able to be relatively appropriately controlled by, for example, the above-mentioned control part. In the motor 1, for example, cooling by the temperature adjuster 50 is able to be strengthened according to an increase or a tendency to increase in a rotation speed of the rotor 20, and is able to be weakened according to a decrease or a tendency to decrease in the rotation speed of the rotor 20.

The cover 80 covers at least a portion of the substrate 70. For example, the cover 80 covers a connection portion between the conducting wire 33 and the substrate 70 and a connection portion between the connection line 52 and the substrate 70. As described above, the motor 1 further includes the cover 80. In this way, the above-mentioned connection portions are able to be protected by the cover 80. Accordingly, disconnection, corrosion or the like at the above-mentioned connection portions is able to be suppressed or prevented.

A portion of the cover 80 preferably seals a portion of the through hole 42 in the axially one direction D1 with respect to the sealing member 421, and more preferably, is in close contact with the sealing member 421. Another portion of the cover 80 preferably seals a portion of the base hole 43 in the axially one direction D1 with respect to the sealing member 431, and more preferably, is in close contact with the sealing member 431.

In this way, by sealing each of the through hole 42 and the base hole 43 by a portion of the cover 80, the airtightness inside the motor 1 is able to be further enhanced.

In the through hole 42 and in the base hole 43, if there is a gap between the cover 80 and each of the sealing member 421 and the sealing member 431, a portion of the cover 80 is likely to be removed from the through hole 42 and the base hole 43. When the portion of the cover 80 is removed, there is a risk that the cover 80 is likely to be peeled off from the above-mentioned connection portions. Accordingly, in the through hole 42 and in the base hole 43, since the cover 80 is in close contact with each of the sealing member 421 and the sealing member 431, the cover 80 is able to be effectively suppressed or prevented from being removed or peeled off.

The above illustration neither excludes a configuration in which a portion of the cover 80 does not seal the through hole 42 nor excludes a configuration in which a portion of the cover 80 that seals the through hole 42 does not contact the sealing member 421. The above illustration neither excludes a configuration in which a portion of the cover 80 does not seal the base hole 43 nor excludes a configuration in which a portion of the cover 80 that seals the base hole 43 does not contact the sealing member 431.

In the present embodiment, an ultraviolet thermosetting adhesive is used for the cover 80. In this adhesive, for example, after a portion of the cover 80 is cured by UV irradiation, the entire cover 80 including a portion that the UV irradiation has failed to reach is able to be cured by heat treatment. However, the material of the cover 80 is not limited to this illustration. A material other than the ultraviolet thermosetting adhesive may be used for the cover 80. For example, like the sealing members 421 and 431, an epoxy-based thermosetting resin may be used. Alternatively, the material of the cover 80 may be different from that of the sealing members 421 and 431. Alternatively, the disclosure is not limited to the above illustration, and the cover 80 may be omitted.

A modification of an embodiment is described with reference to FIG. 3. FIG. 3 is a cross-sectional view illustrating a configuration example of a motor 1a according to a modification. FIG. 3 illustrates a cross-sectional structure of the motor 1a cut along a virtual plane containing the central axis CX. In FIG. 3, the clamp member 23 (see FIG. 1) is omitted from illustration. In the following, a configuration different from the above embodiment will be described. The same components as those in the above embodiment are denoted by the same reference numerals, and the description thereof may be omitted.

In the modification, a shaft hole 11a is a hole extending in the axially other direction D2 from an end of a shaft 10a close to the axially one direction D1, and extends further in the axially other direction D2 than the fluid dynamic pressure bearing Bf close to the axially other direction D2. For example, in FIG. 3, the shaft hole 11a is a through hole penetrating the shaft 10a in the axial direction. However, the disclosure is not limited to the illustration of FIG. 3. The shaft hole 11a does not necessarily reach an end of the shaft 10a close to the axially other direction D2. That is, the shaft hole 11a is not necessarily a through hole. In this way, a connection line 52a of a temperature adjuster 50a is able to be pulled out of the motor 1a through the shaft hole 11a even if the through hole 42 (see FIG. 2) is not provided in a base 40a. Hence, the through hole 42 (see FIG. 2) is omitted.

In FIG. 3, the motor 1a further includes a sealing member 111a that seals the shaft hole 11a. In detail, the sealing member 111a is disposed further in the axially one direction D1 than the temperature adjuster 50a, and seals a side of the shaft hole 11a close to the axially one direction D1. An epoxy-based thermosetting resin, for example, is used for the sealing member 111a. The disclosure is not limited to the illustration of FIG. 3, and the sealing member 111a may be omitted.

In FIG. 3, a portion of a cover 80a seals a portion of the shaft hole 11a in the axially one direction D1 with respect to the sealing member 111a, and is further in close contact with the sealing member 111a. Another portion of the cover 80a seals a portion of a base hole 43a in the axially one direction D1 with respect to a sealing member 431a, and is further in close contact with the sealing member 431a.

By sealing the base hole 43a by a portion of the cover 80a, airtightness inside the motor 1a is able to be further enhanced. In the shaft hole 11a and in the base hole 43a, since the cover 80a is in close contact with each of the sealing member 111a and the sealing member 431a, the cover 80a is able to be effectively suppressed or prevented from being removed or peeled off.

However, the illustration of FIG. 3 neither excludes a configuration in which a portion of the cover 80a does not seal the shaft hole 11a nor excludes a configuration in which a portion of the cover 80a that seals the shaft hole 11a does not contact the sealing member 111a. The illustration of FIG. 3 neither excludes a configuration in which a portion of the cover 80a does not seal the base hole 43a nor excludes a configuration in which a portion of the cover 80 that seals the base hole 43a does not contact the sealing member 431a.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

For example, in the above embodiment and modification thereof, the fluid dynamic pressure bearing Bf is adopted as a bearing that rotatably supports the rotor 20. However, the bearing is not limited to this illustration, and may be a bearing (such as a ball bearing or a slide bearing) other than the fluid dynamic pressure bearing Bf.

The disclosure is useful in, for example, a motor that rotates a rotor with high accuracy, and an apparatus that drives a disk by the motor.

What is claimed is:

1. A motor comprising:
a shaft, extending along a central axis extending in an axial direction;
a base, extending in a radial direction from an end of the shaft in an axially one direction;
a stator, having an annular shape surrounding the shaft, and disposed further in an axially other direction than the base;
a rotor, rotatable about the central axis;
a bearing, rotatably supporting the rotor; and
at least one or more temperature adjusters, adjusting an ambient temperature of the bearing, wherein
the shaft has a shaft hole recessed in the axial direction from an axial end of the shaft; and
the at least one or more temperature adjusters are disposed in the shaft hole and overlap at least a portion of the bearing as viewed in the radial direction.

2. The motor according to claim 1, further comprising:
a heat conductor, disposed between an inner peripheral surface of the shaft hole and the at least one or more temperature adjusters.

3. The motor according to claim 1, wherein
the at least one or more temperature adjusters comprise a Peltier element.

4. The motor according to claim 1, wherein
the shaft further has a communication hole penetrating the shaft in the radial direction, wherein
the communication hole is disposed further in the axially one direction than the bearing.

5. The motor according to claim 4, wherein
the base has a through hole penetrating the base in the axial direction.

6. The motor according to claim 5, wherein
the through hole is disposed radially inward of the stator.

7. The motor according to claim 1, wherein
the shaft hole is a through hole penetrating the shaft in the axial direction.

8. The motor according to claim 5, wherein
the motor further comprises a substrate disposed further in the axially one direction than the base;
the stator comprises a coil part in which a conducting wire is wound into a coil;
the base has a base hole penetrating the base in the axial direction, wherein
the conducting wire is connected to the substrate through the base hole; and
the at least one or more temperature adjusters comprise a connection line connected to the substrate through at least the through hole.

9. The motor according to claim 8, further comprising:
a first sealing member, sealing the base hole.

10. The motor according to claim 9, further comprising:
a cover, covering a connection portion between the conducting wire and the substrate and a connection portion between the connection line and the substrate.

11. The motor according to claim 5, further comprising:
a second sealing member, disposed further in the axially one direction than the at least one or more temperature adjusters and sealing the through hole.

12. The motor according to claim 8, further comprising:
a first sealing member, sealing the base hole;
a second sealing member, disposed further in the axially one direction than the at least one or more temperature adjusters and sealing the through hole; and
a cover, covering a connection portion between the conducting wire and the substrate and a connection portion between the connection line and the substrate, wherein
a portion of the cover seals a portion of the through hole in the axially one direction with respect to the second sealing member and is in close contact with the second sealing member; and
another portion of the cover seals a portion of the base hole in the axially one direction with respect to the first sealing member and is in close contact with the first sealing member.

13. A disk drive apparatus comprising:
the motor according to claim 1;
a disk, supported by the motor; and
an access part, at least either reading information from or writing information to the disk.

14. The disk drive apparatus according to claim 13, further comprising:
a housing, housing the motor, the disk and the access part, wherein
the housing is filled with a gas having a lower density than air.
